(19) United States
(12) Patent Application Publication
(10) Pub. No.: US 2025/0132287 A1
(43) Pub. Date: Apr. 24, 2025

(54) SEMICONDUCTOR PACKAGING METHOD, SEMICONDUCTOR ASSEMBLY COMPONENT AND ELECTRONIC DEVICE

(71) Applicant: Yibu Semiconductor Co., Ltd., Shanghai (CN)

(72) Inventor: Ming Li, Shanghai (CN)

(73) Assignee: Yibu Semiconductor Co., Ltd., Shanghai (CN)

(21) Appl. No.: 18/920,841

(22) Filed: Oct. 18, 2024

(30) Foreign Application Priority Data
Oct. 18, 2023 (CN) 202311353229.9

(51) Int. Cl. H01L 23/00; H01L 21/3105; H01L 21/56; H01L 21/683; H01L 25/065

(52) U.S. Cl. CPC H01L 24/81; H01L 21/31051; H01L 21/565; H01L 21/6835; H01L 24/03; H01L 25/0655; H01L 2224/03614; H01L 2224/03622; H01L 2224/81143; H01L 2224/81203; H01L 2924/37001

(57) ABSTRACT

The semiconductor packaging method forms a semiconductor assembly including a semiconductor device by automatically pulling the semiconductor device to a target position on a carrier using the surface tension generated by alignment solder bumps in a molten state through fusion bonding of first alignment bonding parts on the semiconductor device and second alignment bonding parts on the carrier. The method allows a certain degree of placement deviation when the semiconductor device is picked and placed on the carrier, and accurately fixes the semiconductor device at the target position after the alignment bonding solder bumps are solidified. Thus, drifting and rotation of the semiconductor device in a molding process are prevented. In addition, the active surface and the connecting terminals of the semiconductor device are pre- sealed to avoid height restriction of the connecting terminals, improve the chemical resistance of the connecting terminals, and protect the reliability of the active surface.

### CROSS REFERENCE TO RELATED APPLICATION

The present application claims the benefit of priority under the Paris Convention to Chinese Patent Application No. 202311353229.9, filed on Oct. 18, 2023, which is incorporated herein by reference in its entirety. This application is related to co-pending US Patent Application entitled “Semiconductor packaging method, semiconductor assembly component and electronic device,” filed on even date herewith (Attorney Docket No. YB028-11US), which is incorporated herein by reference in its entirety.

### TECHNICAL Field

The disclosure relates to the field of semiconductor technology, and in particular to a semiconductor packaging method, a semiconductor assembly component and an electronic device.

### BACKGROUND

Semiconductor packaging and systems have been pursued to be compact, small, light, thin in design, while achieving high integration and versatility in functional aspects. Various packaging techniques are currently proposed to meet the above requirements, such as Fan-out Wafer Level packaging, chiplet packaging, heterogeneous integration, 2.5D/3D packaging.

Taking fan-out packaging as an example, the main technical problem it faces is that there is still a lack of efficient and economical methods for high-precision placement and position fixation of chips. In related technologies, fan-out packaging mostly uses expensive placement machines for placement, which have high equipment costs, slow placement speed, and low positioning accuracy. It mainly depends on the accuracy of the placement machine, which has become a major bottleneck in the development and popularization of technology.

### SUMMARY

In order to solve the technical problems, the present disclosure provides a semiconductor packaging method, a semiconductor assembly component and an electronic device.

In the first aspect, the present disclosure provides a semiconductor packaging method, comprising:
Providing a semiconductor device and a carrier; the semiconductor device comprises an active surface and a passive surface which are oppositely arranged, wherein the active surface comprises connecting terminals and a first molding layer, the first molding layer covers the active surface and the connecting terminals, and the passive surface comprises first alignment bonding parts; the surface of one side of the carrier is provided with second alignment bonding parts corresponding to the first alignment bonding parts; either one of the first and second alignment solder portions includes alignment solder bumps, and the others includes alignment pads corresponding to the alignment solder bumps;
The alignment solder bumps are substantially aligned with the alignment pads, and fusion bonding is carried out on the alignment solder bumps and the alignment pads, so that the semiconductor device is accurately aligned and fixed to the carrier;

Forming a second molding layer, wherein the second molding layer covers the surface of the side surface of the carrier facing the semiconductor device that is not occupied by the semiconductor device and covers the semiconductor device, and the second molding layer also fills the gap between the semiconductor device and the carrier.

In some embodiments, the fusion bonding the alignment solder bumps and the alignment pads includes:
Heating the alignment solder bumps so that the alignment solder bumps are at least partially in a molten state;
Bonding the alignment solder bumps which are at least partially in a molten state with the alignment pads.

In some embodiments, the first alignment bonding parts comprises first alignment pads; before the semiconductor device is provided, the semiconductor packaging method further includes:
Forming a first metal layer on the passive surface;
Forming a patterned first photoresist layer on one side of the first metal layer away from the semiconductor device; the first photoresist layer comprises first openings, and the first openings exposes the first metal layer;
Etching the first metal layer exposed by the first openings based on the patterned first photoresist layer;
Removing the first photoresist layer to expose the first alignment pads.

In some embodiments, the first alignment bonding parts comprises first alignment solder bumps; the semiconductor packaging method further comprises the steps of:
Forming first alignment solder bumps on one side of the first alignment bonding pads, which is away from the semiconductor device.

In some embodiments, the second alignment bonding parts includes second alignment pads; before providing of the carrier, the semiconductor packaging method further comprises the following steps:
Forming a second metal layer on one side of the carrier;
Forming a patterned second photoresist layer on one side of the second metal layer away from the carrier; the second photoresist layer comprises second openings, and the second openings exposes the second metal layer;
Etching the metal layer exposed by the second openings based on the second photoresist layer;
Removing the second photoresist layer to expose the second alignment bonding pads of the second alignment bonding parts.

In some embodiments, the second alignment bonding parts comprises second alignment solder bumps; the semiconductor packaging method further comprises the steps of:
Forming second alignment bonding bumps on one side of the second alignment bonding pads, which is away from the carrier.

In some embodiments, before forming the first alignment pads on the passive surface, the semiconductor packaging method further includes:
Forming connection terminals on the active surface;
Forming the first molding layer on one side of the connecting terminals, which is away from the semiconductor device; the first molding layer covers the active surface and the connecting terminals.

In some embodiments, the semiconductor packaging method further includes:
The carrier is removed using at least one of lift-off, etching, ablation, and grinding processes.

In some embodiments, after removing the carrier, the semiconductor packaging method further includes:
Thinning the surface of the second molding layer, which is near one side of the second alignment bonding parts.

In some embodiments, the semiconductor packaging method further includes:
Thinning the first molding layer to expose the connecting terminals;
Forming an interconnection layer and external terminals on the surface of one side of the first molding layer, which is exposed from the connection terminals; The connection terminals are electrically connected with the external terminals through the interconnection layer.

In the second aspect, the present disclosure also provides a semiconductor assembly packaged by any one of the above semiconductor packaging methods.

In the third aspect, the present disclosure also provides an electronic device, including: the semiconductor assembly.

Compared with the prior technology, the technical scheme provided by the disclosure has the following advantages:

The present disclosure provides a semiconductor packaging method, a semiconductor assembly, and an electronic device, the semiconductor packaging method including: providing a semiconductor device and a carrier; the semiconductor device comprises an active surface and a passive surface which are oppositely arranged, wherein the active surface comprises connecting terminals and a first molding layer, the first molding layer covers the active surface and the connecting terminals, and the passive surface comprises first alignment bonding parts; one side surface of the carrier is provided with second alignment bonding parts corresponding to the first alignment bonding parts; either one of the first alignment bonding parts and the second alignment bonding parts includes alignment solder bumps, and the others include alignment pads corresponding to the alignment solder bumps; the alignment solder bumps and the alignment pads are substantially aligned, and fusion bonding is carried out on the alignment solder bumps and the alignment pads, so that the semiconductor device is accurately aligned and fixed to the carrier; and forming a second molding layer, wherein the second molding layer covers the semiconductor device and the surface of the side surface of the carrier facing the semiconductor device that is not occupied by the semiconductor device and covers the semiconductor device, and the second molding layer fills the gap between the semiconductor device and the carrier. Therefore, the first alignment bonding parts and the second alignment bonding parts are subjected to fusion bonding process, the semiconductor device is automatically pulled to the target position on the carrier by surface tension generated by the alignment solder bumps in a fusion state based on the minimum surface energy principle, the semiconductor device is accurately fixed at the target position by the alignment solder bumps after cooling down, the semiconductor device is prevented from drifting and rotating in the molding process, and the yield of the subsequent process can be effectively improved; in view of the self-alignment capability of aligning the solder bumps, a certain degree of placement deviation is allowed when the semiconductor device is picked and placed, namely, the requirement on the placement precision of the semiconductor device is reduced, so that the speed of the semiconductor device picking and placement operation is improved, the process efficiency is further improved, thus the process cost is reduced; in addition, the active surface and the connecting terminals of the semiconductor device are pre-sealed to solve the height restriction of the active surface to the connecting terminals, improve the chemical resistance of the connecting terminals and the protection reliability of the active surface.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure.

In order to more clearly illustrate the embodiments of the present disclosure or the solutions in the prior technology, the drawings that are required for the description of the embodiments or the prior technology will be briefly described below, and it will be obvious to those skilled in the art that other drawings can be obtained from these drawings without inventive effort.

FIG. 1 is a schematic flow chart of a semiconductor packaging method according to an embodiment of the disclosure;

FIG. 2 is a schematic structural diagram corresponding to each step in the semiconductor packaging method shown in FIG. 1;

FIG. 3 is a schematic diagram of another structure corresponding to each step in the semiconductor packaging method shown in FIG. 1;

FIG. 4 is a flow chart of another semiconductor packaging method according to an embodiment of the disclosure;

FIG. 5 is a schematic structural diagram corresponding to each manufacturing step of the semiconductor device according to the embodiment of the disclosure;

FIG. 6 is a schematic structural diagram corresponding to each preparation step of a carrier board according to an embodiment of the disclosure;

FIG. 7 is a flow chart illustrating another semiconductor packaging method according to an embodiment of the disclosure;

FIG. 8 is a schematic structural diagram of a semiconductor device according to an embodiment of the disclosure;

FIG. 9 is a schematic structural diagram of another semiconductor device according to an embodiment of the present disclosure.

### DETAILED DESCRIPTION OF THE EMBODIMENTS

In order to more clearly understand the above-mentioned purposes, features and advantages of the present disclosure, a further description of aspects of the present disclosure will be provided below. It should be noted that, without conflict, the embodiments of the present disclosure and features in the embodiments may be combined with each other.

In the following description, numerous specific details are set forth to provide a thorough understanding of the present disclosure, however, the present disclosure may also be implemented in other ways different from those described herein. it will be apparent that the embodiments in the specification are only some, but not all, embodiments of the disclosure.

In the related technology, fan-out packaging typically employs a molding compound to encapsulate a single or multiple good dies from a diced wafer and to route interconnect traces from the connection pads of the die to external solder balls via a redistribution layer to achieve higher I/O density and flexible integration. In the current technical problems of fan-out packaging, high-precision placement and position fixing of wafers still lack an efficient and economical method, a chip mounter with high price is generally adopted for die mounting, and the alignment precision of the dies depends on the precision of the chip mounter and is generally larger than ±2 μm. Often, the higher the placement accuracy of the chip mounter, the higher the equipment cost and the lower the production efficiency.

In order to solve the above technical problems, embodiments of the present disclosure provide a semiconductor packaging method, a semiconductor assembly, and an electronic device, the semiconductor packaging method including: providing a semiconductor device and a carrier; the semiconductor device comprises an active surface and a passive surface which are oppositely arranged, wherein the active surface comprises connecting terminals and a first molding layer, the first molding layer covers the active surface and the connecting terminals, and the passive surface comprises first alignment bonding parts; one side surface of the carrier is provided with second alignment bonding parts corresponding to the first alignment bonding parts; either one of the first alignment bonding parts and the second alignment bonding parts include alignment solder bumps, and the others include alignment pads corresponding to the alignment solder bumps; the alignment solder bumps and the alignment pads are substantially aligned, and fusion bonding is carried out on the alignment solder bumps and the alignment pads, so that the semiconductor device is accurately aligned and fixed to the carrier; and then forming a second molding layer, wherein the second molding layer covers the semiconductor device and the surface of the side surface of the carrier facing the semiconductor device that is not occupied by the semiconductor device and covers the semiconductor device,, and the second molding layer fills the gap between the semiconductor device and the carrier. Therefore, the first alignment bonding parts and the second alignment bonding parts are subjected to fusion bonding, the semiconductor device is automatically pulled to the target position of the carrier by surface tension generated by the alignment solder bumps in a fusion state based on the minimum surface energy principle, the semiconductor device is accurately fixed at the target position by the alignment pads after cooling down, the semiconductor device is prevented from drifting and rotating in the molding process, and the yield of the subsequent process can be effectively improved; in view of the self-alignment capability of aligning the solder bumps, a certain degree of placement deviation is allowed when the semiconductor device is picked and placed, namely, the requirement on the placement precision of the semiconductor device is reduced, so that the speed of the semiconductor device picking and placement operation is improved, the process efficiency is further improved, thus the process cost is reduced; in addition, the active surface and the connecting terminals of the semiconductor device are pre-sealed to solve the height restriction of the active surface to the connecting terminals, and improve the chemical resistance of the connecting terminals and the protection reliability of the active surface.

The following describes exemplary embodiments of a semiconductor packaging method, a semiconductor assembly, and an electronic device according to embodiments of the present disclosure with reference to the accompanying drawings.

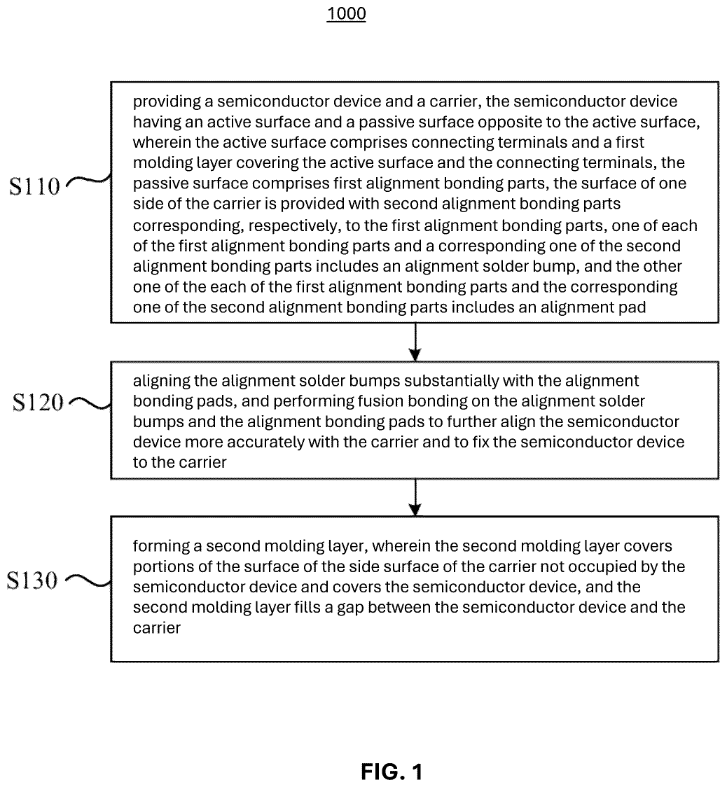

In some embodiments, as shown in FIG. 1, a flow chart of a semiconductor packaging method 1000 according to an embodiment of the disclosure is shown. Referring to FIG. 1, the semiconductor packaging method 1000 includes the steps of:

S110, providing a semiconductor device and a carrier; the semiconductor device comprises an active surface and a passive surface which are oppositely arranged, wherein the active surface comprises connecting terminals and a first molding layer, the first molding layer covers the active surface and the connecting terminals, and the passive surface comprises first alignment bonding parts; one side surface of the carrier is provided with second alignment bonding parts corresponding to the first alignment bonding parts; either one of the first and second alignment bonding parts includes alignment solder bumps, and the other includes alignment pads corresponding to the alignment solder bumps.

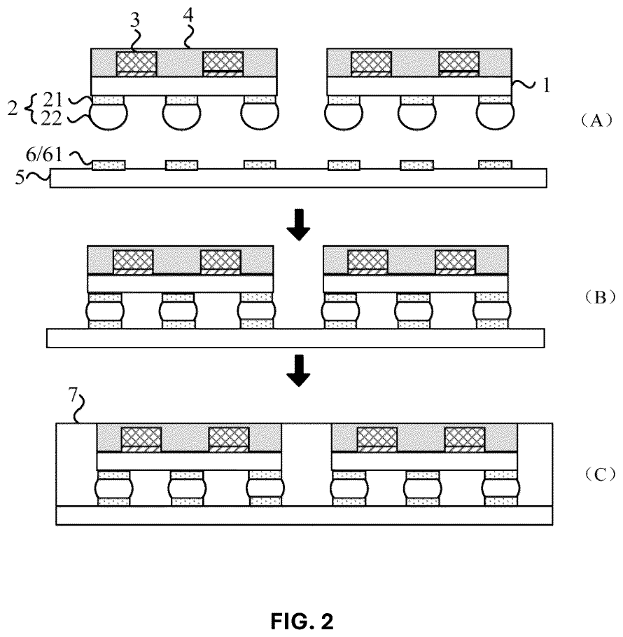

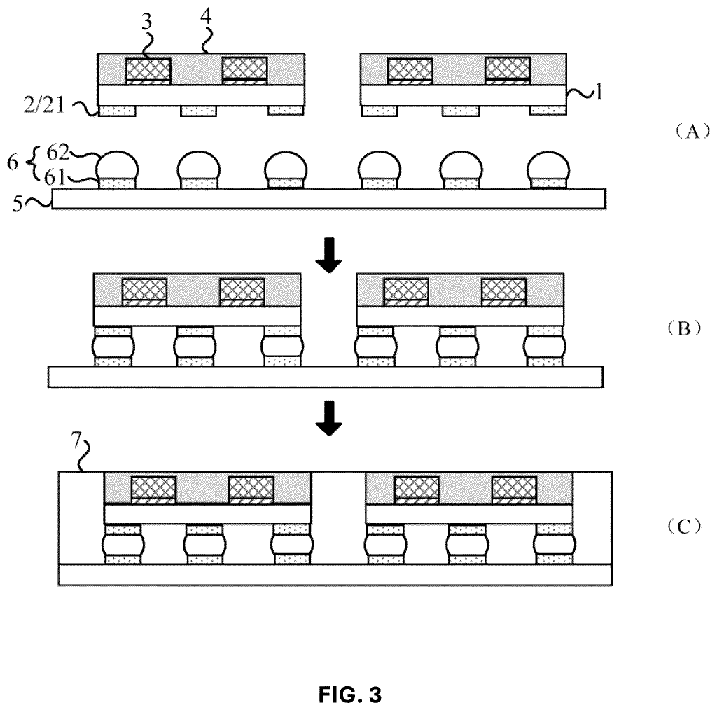

In this embodiment, in connection with FIG. 2 or 3, the semiconductor device 1 includes, but is not limited to, a die and a chip. The semiconductor device 1 comprises a passive surface and an active surface which are oppositely arranged, the active surface is provided with connecting terminals 3 and a first molding layer 4, the first molding layer 4 covers the connecting terminals 3 and the surface of the active surface not occupied by the connecting terminals 3, the passive surface of the semiconductor device is arranged on a plurality of first alignment bonding partss 2. The first molding layer 4 is used for solidifying and protecting the connecting terminals 3, so that the limit on the height of the connecting terminals 3 is solved, and meanwhile, the coating of the first molding layer 4 is beneficial to improving the chemical resistance of the connecting terminals 3 and the protection reliability of an active surface. The connection terminals 3 are used for electrical connection with the interconnect layers and the external terminals in the subsequent steps to achieve electrical connection of the semiconductor device 1 with the external devices.

The carrier 5 is not limited in the embodiments of the present disclosure, and any type of carrier known to those skilled in the art may be used, for example, the carrier 5 includes at least one of glass carriers, ceramic carriers, metal carriers, organic polymer material carriers, and silicon wafers. Second alignment bonding parts 6 corresponding to the first alignment bonding parts 2 are provided on one side of the carrier 5

The first alignment bonding parts 2 are one of the alignment solder bumps and the alignment pads, and the second alignment bonding parts 6 is the other of the alignment solder bumps and the alignment pads. In other embodiments, as shown in FIG. 2, the first alignment bonding parts 2 are alignment solder bumps and the second alignment bonding parts 6 is alignment bonding pads. In other embodiments, as shown in FIG. 3, the first alignment bonding parts 2 are alignment pads and the second alignment bonding parts 6 are alignment solder bumps. The shape of the alignment solder bumps may be spherical or columnar and is not limited thereto.

It should be noted that the number of semiconductor devices 1 in the embodiment of the present disclosure is not limited, and FIGS. 2 to 3 only exemplarily illustrate that two semiconductor devices 1 are fixed on the carrier 5, and the number of the semiconductor devices 1 may be set according to the need, for example, one, three, or more.

S120, substantially aligning the alignment solder bumps with the alignment pads, and carrying out fusion bonding on the alignment solder bumps and the alignment pads so that the semiconductor device is accurately aligned and fixed on the carrier.

In some embodiments, “Substantial Alignment” of the first alignment bonding parts 2 and the second alignment bonding parts 6 means that the first alignment bonding parts 2 and the second alignment bonding parts 6, respectively, are in contact with each other, but are not exactly centered in a direction perpendicular to the passive surface. “Centered” herein generally means that the centers of the first alignment bonding parts 2 and the second alignment bonding parts 6 are aligned in a direction perpendicular to the passive surface. “Precise Alignment” means a state in which a deviation between an actual position of the semiconductor device 1 on the carrier 5 and a target position is within a tolerance range in technology.

In some embodiments, the alignment solder bumps are made of solder, and the fusion bonding can adopt all fusion bonding modes known by a person skilled in technology, including but not limited to reflow bonding, laser bonding, high-frequency bonding, infrared bonding and the like.

In this step, when the semiconductor device 1 put on the carrier 5, the passive face of the semiconductor device 1 faces the carrier 5, the active face of the semiconductor device 1 faces away from the carrier 5, and the first alignment bonding parts 2 and the second alignment bonding parts 6 are in contact with each other but are not exactly centered in a direction perpendicular to the passive face of the semiconductor device 1 or the carrier 5; during the soldering process, one of the first and second alignment bonding partss 2 and 6 serving as alignment soldering bumps are melted or partially melted and infiltrated into the other one of the alignment pads, and at this time, the alignment soldering bumps in a melted or partially melted state tends to deform and move to bring the first alignment bonding parts 2 and the second alignment bonding parts 6 close to a centered state based on the minimum surface energy principle, thereby bringing the lighter semiconductor device 1 into precise alignment to a target position on the carrier 5 (i.e., a position where the second alignment bonding parts 6 is located). After the alignment solder bumps are cooled, the semiconductor device 1 is precisely fixed at the target position on the carrier 5, so that high-strength mechanical fixation (reaching the kilogram force level) of the semiconductor device 1 and the carrier 5 is realized, the drift and rotation problems of the semiconductor device 1 on the carrier 5 in the subsequent molding process are solved, and the yield of the subsequent working procedures is effectively improved.

After the first alignment bonding parts 2 and the second alignment bonding parts 6 are bonded, the bonding structure formed by the bonding of the two parts has a certain height, so that the passive surface of the semiconductor device 1 and the carrier 5 are separated to form a certain space therebetween.

S130, forming a second molding layer, wherein the second molding layer covers the surface of the side surface of the carrier facing the semiconductor device that is not occupied by the semiconductor device and covers the semiconductor device, and the second molding layer fills the gap between the semiconductor device and the carrier.

In this step, the molding process such as transfer molding, compression molding or printing may be used to perform the molding, and the material for preparing the second molding layer 7 includes a molding compound of a resin material (for example, epoxy resin). The second molding layer 7 and the semiconductor device 1 are located on the same side of the carrier 5, and the second molding layer 7 not only covers the surface not occupied by the semiconductor device 1 of the carrier 5, but also covers the side surface of the semiconductor device 1, and fills the gap between the passive surface of the semiconductor device 1 and the carrier 5.

According to the semiconductor packaging method provided by the embodiment of the disclosure, the first alignment bonding parts 2 and the second alignment bonding parts 6 are subjected to fusion bonding, the semiconductor device 1 is automatically pulled to the target position of the carrier 5 by the surface tension generated by the alignment solder bumps in the fusion state based on the minimum surface energy principle, the semiconductor device 1 is accurately fixed at the target position after the alignment solder bumps are cooled, the semiconductor device 1 is prevented from drifting and rotating in the molding process, and the yield of the subsequent process can be effectively improved; in view of the self-alignment capability of aligning the solder bumps, a certain degree of placement deviation is allowed when the semiconductor device is picked and placed, namely, the requirement on the placement precision of the semiconductor device 1 is reduced, so that the speed of the picking and placement operation of the semiconductor device 1 is improved, the process efficiency is further improved, thus the process cost is reduced; in addition, the active surface of the semiconductor device 1 and the connection terminals 3 are pre-sealed to solve the height restriction of the active surface to the connection terminals 3, and improves the chemical resistance of the connection terminals and the protection reliability of the active surface.

By way of example, the semiconductor packaging method provided in this embodiment is used for packaging, and a common chip mounter can be used to achieve automatic alignment of the semiconductor device 1 within a chip mounting error range of ±10 μm. After self-alignment, the position accuracy of the semiconductor device 1 is less than or equal to ±1 μm, the rotation accuracy is less than or equal to ±0.01 degrees, and the chip mounting speed can reach 11,000 pieces/hour.

In some embodiments, the first alignment bonding parts 2 corresponds to the second alignment bonding parts 6 in terms of volume, size, geometry, composition, distribution, position, number, etc. such that the semiconductor device 1 can be precisely aligned to a respective target position on the carrier 5 by bonded to each other.

It should be understood that the detail volume, size, geometry, composition, distribution, location, and number of the first alignment bonding parts 2 and/or the second alignment bonding parts 6 may be appropriately selected according to specific process conditions or actual requirements (e.g., the size shape of the carrier 5 and the semiconductor device 1, the placement pitch or package size and shape of the semiconductor device 1, etc.), and the embodiments of the present disclosure are not particularly limited thereto. For example, for all the semiconductor devices 1, the first alignment bonding parts 2 may be formed to have substantially the same volume, size, geometry, or composition regardless of whether the functions, sizes, or shapes are the same as each other, and the second alignment bonding parts 6 on the carrier 5 may be formed to have substantially the same volume, size, geometry, or composition, so as to reduce the complexity of the subsequent processes and to improve the packaging efficiency. For another example, the semiconductor devices 1 have the different functions, sizes or shapes, and the first alignment bonding parts 2 and the second alignment bonding parts 6 may be formed in different volumes, sizes, geometries or compositions so that different solder joint heights may be formed after subsequent bonding to achieve a particular function or to meet a particular requirement.

In some embodiments, “performing fusion bonding on the alignment solder bumps to the alignment pads” includes the steps of:
Heating the alignment solder bumps so that the alignment solder bumps are at least partially in a molten state;
The alignment solder bumps to be at least in a molten state are soldered to the alignment pads.

In this embodiment, the bonding may be performed by any fusion bonding methods known to those skilled in technology, including, but not limited to, reflow bonding, laser bonding, high frequency bonding, infrared bonding, and the like. The alignment solder bumps are heated to the melting point, part of the alignment solder bumps are in a molten state or all of the alignment solder bumps are in a molten state, the surface tension generated by the alignment solder bumps in the molten state can automatically pull the semiconductor device 1 to a target position (namely the position of the second alignment bonding parts 6) on the carrier 5, after the alignment solder bumps are cooled, the semiconductor device 1 is precisely fixed at the target position on the carrier 5, the self-alignment of the semiconductor device 1 is realized, and the requirement on the placement precision of the semiconductor device 1 is reduced.

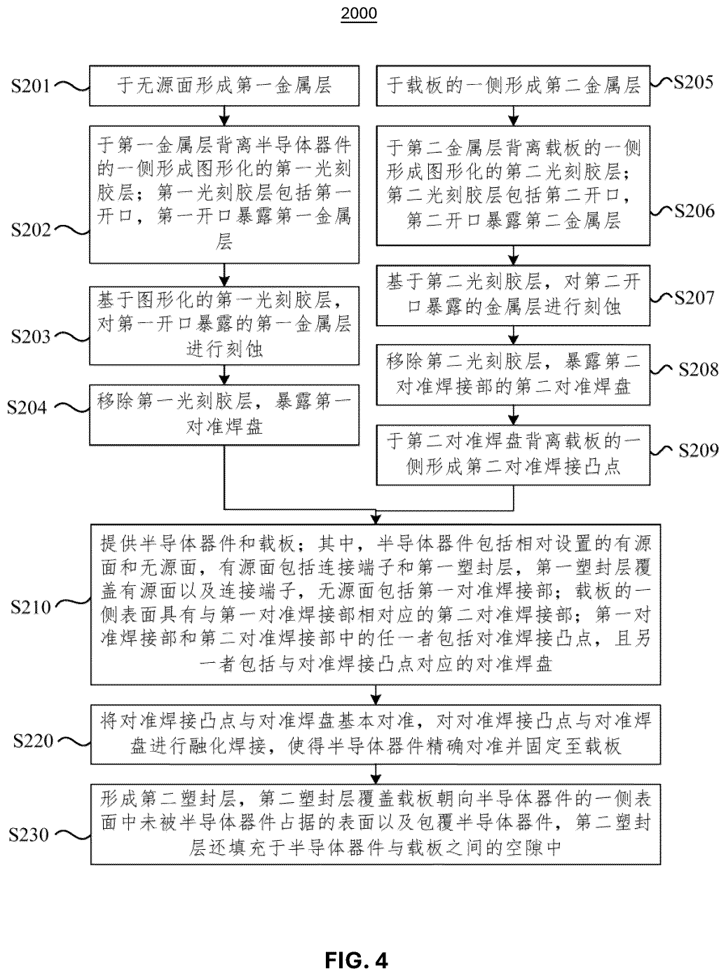

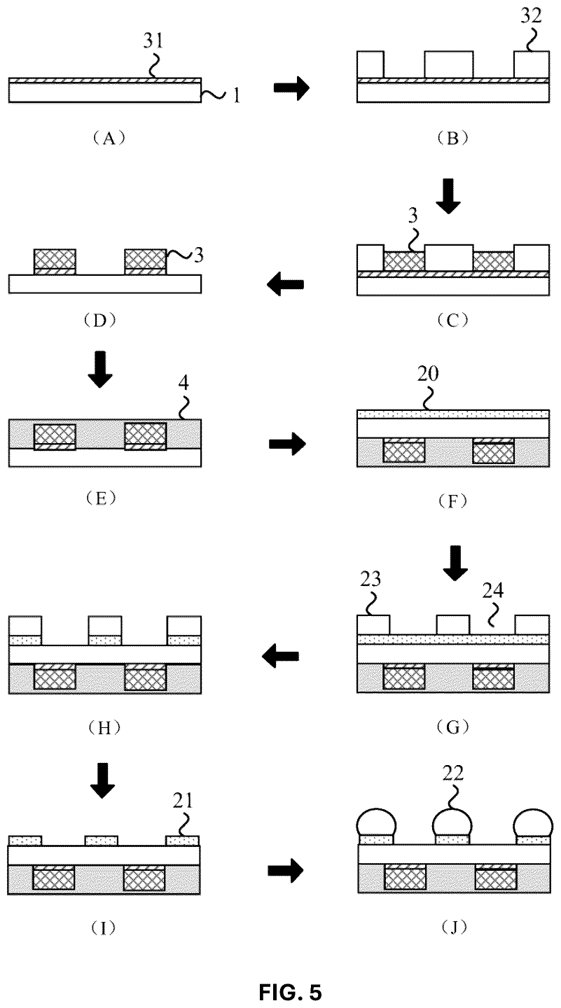

In some embodiments, as shown in FIGS. 4-5, the first alignment bond includes first alignment pads; before “providing a semiconductor device”, a semiconductor packaging method 2000 includes some or all of method 1000 and further includes the steps of:

S201, forming a first metal layer on the passive surface.

In this step, as shown in step (F) of FIG. 5, a first metal layer 20 is formed on and covers the inactive surface of the semiconductor device 1, and the first metal layer 20 includes, but is not limited to, copper and aluminum, and further includes other metals known to those skilled in technology, which are not limited herein.

S202, forming a patterned first photoresist layer on one side of the first metal layer, which is away from the semiconductor device; the first photoresist layer includes first openings exposing the first metal layer.

In this step, as shown in step (G) in FIG. 5, a first photoresist layer 23 is coated on a surface of the first metal layer 20 facing away from the semiconductor device 1, the first photoresist layer 23 is subjected to exposure and development, and first openings 24 is formed in the first photoresist layer 23, so as to obtain a patterned first photoresist layer 23, and the bottom of the first openings 24 exposes the first metal layer 20.

The first photoresist layer 23 may be a positive photoresist, or a negative photoresist, which is not limited herein. If the first photoresist layer 23 is a positive photoresist, exposing the photoresist at the position corresponding to the first openings 24, and dissolving the photoresist at the position during development to form the first openings 24 in the first photoresist layer 23; if the first photoresist layer 23 is a negative photoresist, the photoresist except for the position corresponding to the first openings 24 is exposed, and the photoresist not exposed is dissolved during development, i.e., the photoresist at the position corresponding to the first openings 24 is dissolved, so that the first openings 24 is formed in the first photoresist layer 23.

S203, etching the first metal layer exposed by the first openings based on the patterned first photoresist layer.

In this step, as shown in step (H) in FIG. 5, the first metal layer 20 exposed in the first openings 24 is etched until the first metal layer 20 is etched through and the passive surface of the semiconductor device 1 is exposed.

S204, removing the first photoresist layer to expose the first alignment bonding pads.

In this step, as shown in step (I) of FIG. 5, the first metal layer 20 under the first photoresist layer 23 is not etched, the first photoresist layer 23 is removed, and the remaining first metal layer 20 is the first alignment bonding pads 21. The shape of the first alignment bonding pads 21 is affected by the shape of the patterned first photoresist layer 23.

In this embodiment, the first alignment bonding parts 2 are alignment pads, and the second alignment bonding parts 6 is alignment solder bumps.

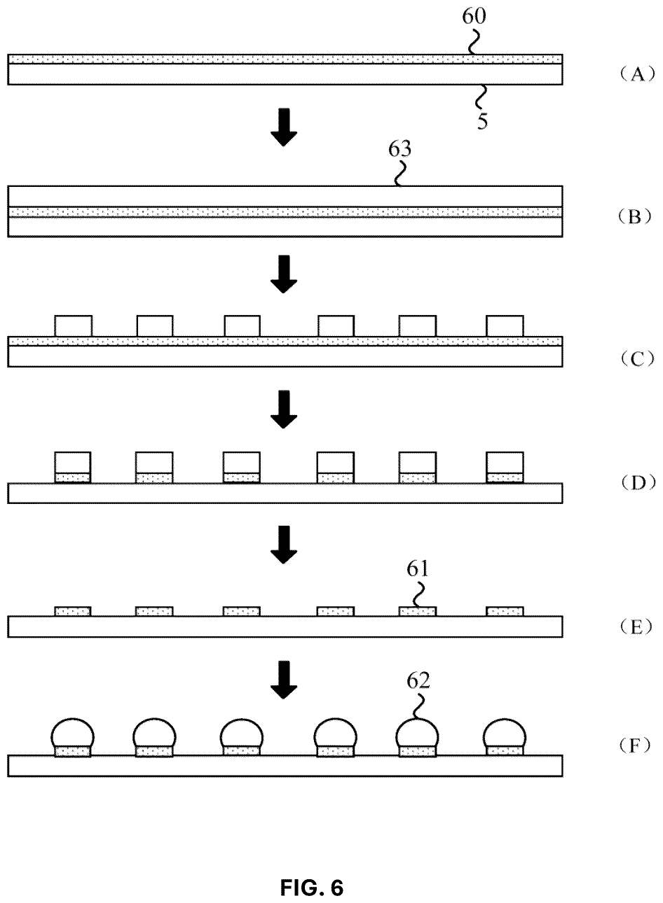

In some embodiments, as shown in FIGS. 4 and 6, the second alignment bonding parts 6 comprises second alignment solder bumps; the semiconductor packaging method further comprises the following steps:

S205, forming a second metal layer on one side of the carrier.

In this step, as shown in step (A) in FIG. 6, a second metal layer 60 is formed on one side of the carrier 5 and covers the surface of the carrier 5, and the second metal layer 60 includes, but is not limited to, copper and aluminum, and other metals known to those skilled in the art, which are not limited herein.

S206, forming a patterned second photoresist layer on one side of the second metal layer, which is away from the carrier. The second photoresist layer includes second openings exposing the second metal layer.

In this step, as shown in steps (B) and (C) in FIG. 6, a second photoresist layer 63 is coated on a side surface of the second metal layer 60 facing away from the carrier 5, the second photoresist layer 63 is exposed and developed, and second openings 64 is formed in the second photoresist layer 63, so as to obtain a patterned second photoresist layer 63, and the bottom of the second openings 64 exposes the second metal layer 60. The second photoresist layer 63 may be a positive photoresist or a negative photoresist, which is not limited herein.

S207, etching the metal layer exposed by the second openings based on the second photoresist layer.

In this step, as shown in step (D) in FIG. 6, the second metal layer 60 exposed in the second openings 64 is etched until the second metal layer 60 is etched through and the carrier 5 is exposed.

S208, removing the second photoresist layer to expose the second alignment bonding pads of the second alignment bonding.

In this step, as shown in step (E) of FIG. 6, the second metal layer 60 under the second photoresist layer 63 is not etched, the second photoresist layer 63 is removed, and the remaining second metal layer 60 is the second alignment bonding pads 61. The shape of the second alignment bonding pads 61 is affected by the shape of the patterned second photoresist layer 63.

S209, forming second alignment solder bumps on one side of the second alignment bonding pads, which is away from the carrier.

In this step, as shown in step (F) of FIG. 6, second alignment solder bumps 62 may be formed on the second alignment bonding pads 61 using an electroplating method, a ball-mounting method, stencil printing method, or an evaporation/sputtering method. The shape of the second alignment solder bumps 62 may be spherical or columnar and is not limited herein.

In the present embodiment, the execution order of S201 to S204 and S205 to S209 is not limited, and S201 to S204 and S205 to S209 may be executed simultaneously, or S201 to S204 may be executed first, S205 to S209 may be executed later, or S205 to S209 may be executed first, and S201 to S204 may be executed later.

Note that, the embodiment of the present disclosure only exemplary illustrates that the first alignment bonding pads 21 and the second alignment bonding pads 61 are fabricated by using a reverse etching method but does not constitute a limitation of the semiconductor packaging method provided by the embodiment of the present disclosure. In other embodiments, other processes known to those skilled in the art may be used to fabricate the first alignment bonding pads 21 and the second alignment bonding pads 61, for example, first covering the passive surface (or the surface of the side of the carrier 5) of the semiconductor device 1 with a seed layer, then forming a patterned photoresist layer, then forming a metal layer in the openings of the photoresist layer, and removing the photoresist layer and the seed layer below the photoresist layer to complete the fabrication of the first alignment bonding pads 21 (or the second alignment bonding pads 61), which is not limited herein.

In this embodiment, S210 to S230 are the same as S110 to S130 and are specifically described with reference to S110 to S130, and are not described herein.

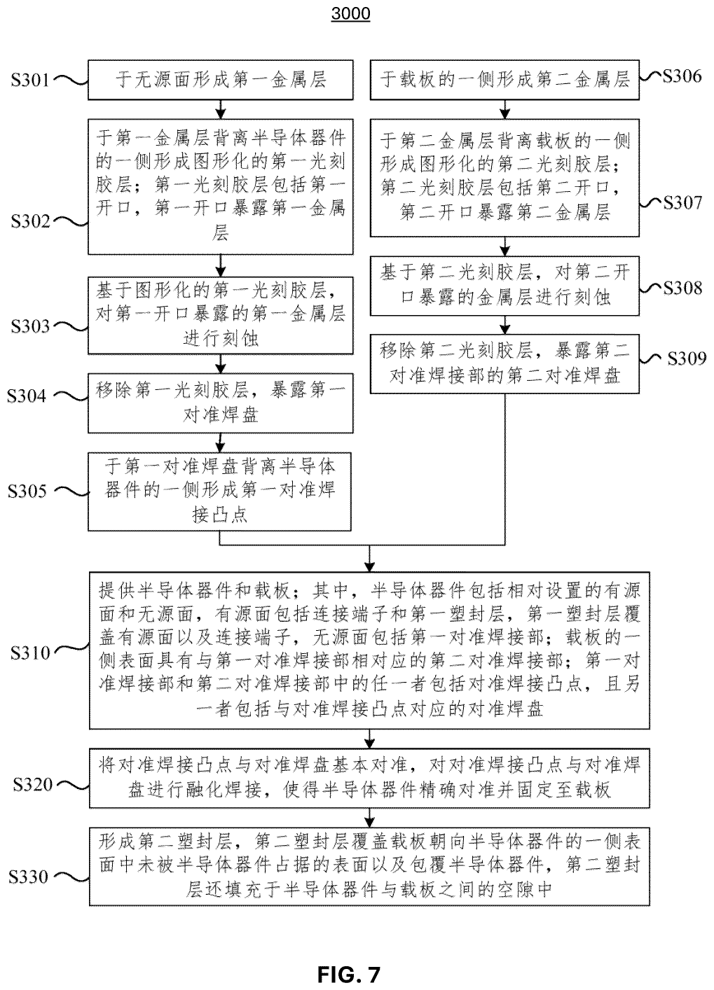

In some embodiments, as shown in FIGS. 5 and 7, the first alignment bonding parts includes first alignment solder bumps; a semiconductor packaging method 3000 includes some or all of the steps in method 1000 and method 2000, and further comprises the following steps:

S301, forming a first metal layer on the passive surface.

S302, forming a patterned first photoresist layer on one side of the first metal layer, which is away from the semiconductor device; the first photoresist layer includes first openings exposing the first metal layer.

S303, etching the first metal layer exposed by the first openings based on the patterned first photoresist layer.

S304, removing the first photoresist layer to expose the first alignment bonding pads.

In this embodiment, S301 to S304 are the same as S201 to S204, and specific reference may be made to the explanation of S201 to S204, and the details are not repeated here.

S305, forming first alignment solder bumps on one side of the first alignment bonding pads, which is away from the semiconductor device.

In this step, as shown in step (J) of FIG. 5, the first alignment solder bumps 22 may be formed on the first alignment bonding pads 21 using an electroplating method, a ball-plating method, a stencil printing method, or an evaporation/sputtering method. The shape of the first alignment solder bumps 22 may be spherical or columnar and is not limited herein.

If the first alignment bonding partss 2 are alignment pads, steps S301 to S304 (or steps S201 to S204) may be performed only; if the first alignment bonding partss 2 are alignment solder bumps, the step S305 is also performed on this basis.

In some embodiments, as shown in FIGS. 6 and 7, the second alignment bonding parts includes second alignment bonding pads; before the carrier is provided, the semiconductor packaging method further comprises the following steps:

S306, forming a second metal layer on one side of the carrier.

S307, forming a patterned second photoresist layer on one side of the second metal layer away from the carrier. The second photoresist layer includes second openings exposing the second metal layer.

S308, etching the metal layer exposed by the second openings based on the second photoresist layer.

S309, removing the second photoresist layer to expose the second alignment bonding pads of the second alignment bonding.

In this embodiment, The S306 to S309 are the same as S205 to S208, and specific reference may be made to the explanation of S205 to S208, and the details are not repeated here.

If the second alignment bonding partss 6 is alignment bonding pads, steps S306 to S309 (or steps S205 to S208) may be performed; if the second alignment bonding partss 6 is alignment solder bumps, step S209 is also performed on this basis.

In some embodiments, as shown in FIG. 5, before the passive face forms the first alignment bond, the semiconductor packaging method further includes the steps of:
Forming connection terminals on the active surface;
Forming a first molding layer on one side of the connecting terminals away from the semiconductor device; the first molding layer covers the active surface and the connecting terminals.

In this embodiment, as shown in FIG. 5, the connection terminals 3 and the first molding layer 4 are formed on the active surface of the semiconductor device 1, and then the first alignment bonding parts 2 are formed on the active surface of the semiconductor device 1. Referring specifically to steps (A)-(E) in FIG. 5, a seed layer 31 is formed on the active surface of the semiconductor device 1, then a third photoresist layer 32 is coated on the side of the seed layer 31 away from the semiconductor device 1, the third photoresist layer 32 is subjected to exposure and development treatment, a third openings 33 is formed in the third photoresist layer 32, and the bottom of the third openings 33 exposes the seed layer 31; in the third openings 33, the connection terminals 3 is formed, the third photoresist layer 32 and the seed layer 32 under the third photoresist layer 31 are removed, and the connection terminals 3 and the seed layer 31 under the connection terminals 3 remain on the active face of the semiconductor device 1. Then, one of the molding processes such as injection molding, compression molding or printing is used for molding, and the first molding layer 4 covers one side surface and the side surface of the connection terminals 3 facing away from the semiconductor device 1 and also covers the surface of the active surface, which is not occupied by the connection terminals 3. The material for the first molding layer 4 includes a molding compound of a resin material (e.g., epoxy resin).

It should be noted that the semiconductor device 1 shown in FIG. 5 is an uncut wafer, and the wafer is divided into regions, and each region corresponds to one die; the connection terminals 3 and the first molding layer 4 are formed on the active surface of each area, the first alignment bonding parts 2 are formed on the passive surface of each area, and then the wafer is cut to obtain the semiconductor device 1 with the connection terminals 3, the first molding layer 4 and the first alignment bonding parts 2, wherein the semiconductor device 1 can be used for being connected with a carrier with the second alignment bonding. Thus, the packaging efficiency is improved. Wherein the wafer saw process includes at least one dicing saw, dicing blades, laser grooving, and plasma cutting processes.

In some embodiments, after “forming the second molding layer”, the semiconductor packaging method further includes the steps of:

The carrier is removed using at least one of lift-off, etching, ablation, and grinding processes.

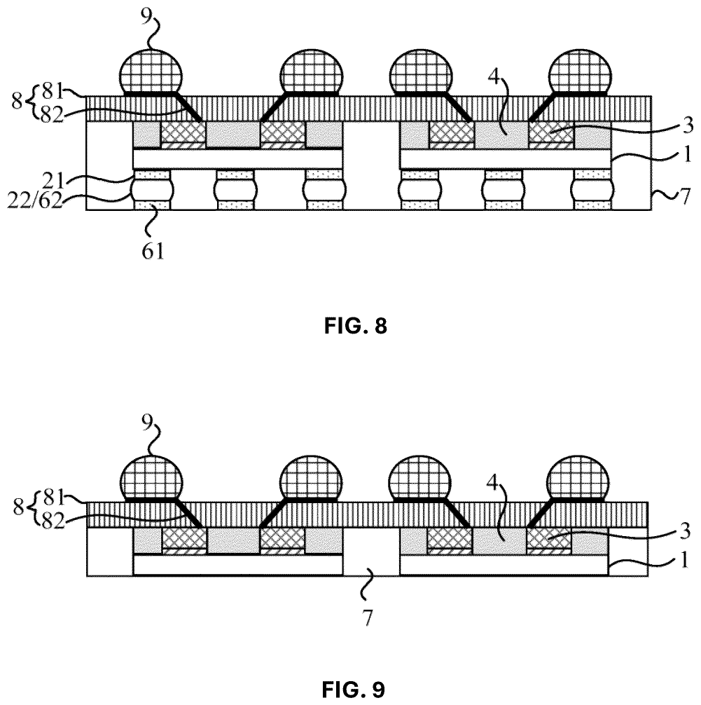

In this embodiment, other processes besides stripping, etching, ablation and grinding processes can be used to remove the carrier 5, which are not limited herein, as will be appreciated by those skilled in technology. As shown in FIG. 8, after the carrier 5 is removed, a side surface of the second molding layer 7 near the second alignment bonding parts 6 is exposed.

In some embodiments, after removing the carrier, the semiconductor packaging method further comprises the steps of:

Thinning the surface of the second molding layer, which is near one side of the second alignment bonding parts.

In this embodiment, when the carrier 5 is removed or after the carrier 5 is removed, the surface of the second molding layer 7 near the second alignment bonding parts are thinned by a process such as debonding, etching, ablation or grinding, so as to remove at least a part of the structure except the passive surface of the semiconductor device 1, thereby further reducing the thickness of the final semiconductor assembly.

The bonding structure formed after the first alignment bonding parts and the second alignment bonding parts are soldered includes the first alignment bonding pads 21, the first alignment bonding pads 21 (or the second alignment solder bumps 62), and the second alignment bonding pads 61. The thickness of the thinned semiconductor device 1 is not limited in this embodiment, and as shown in FIG. 9, the thinned semiconductor device 1 may be thinned to the passive surface, and all structures except the passive surface of the semiconductor device 1, that is, the first alignment bonding pads 21, the first alignment solder bumps 22 (or the second alignment solder bumps 62), the second alignment bonding pads 61, and the corresponding second molding layer 7 are removed; it is also possible to thin down to any position outside the passive surface, to remove part of the structure outside the passive plane of the semiconductor device 1, for example to remove only the second alignment bonding pads 61 and the corresponding second molding layer 7, or to remove the first alignment solder bumps 22 (or the second alignment solder bumps 62), the second alignment bonding pads 61 and the corresponding second molding layer 7.

In some embodiments, the semiconductor packaging method further comprises the steps of:
Thinning the first molding layer to expose the connecting terminals;
Forming an interconnection layer and external terminals on the surface of one side of the first molding layer, which is exposed from the connection terminals; the connection terminals are electrically connected with the external terminals through the interconnection layer.

In this embodiment, the first molding layer 4 is thinned by at least one of the chemical mechanical polishing (Chemical Mechanical Polishing, CMP) grinding, etching and ablation processes until the connection terminals 3 are exposed. As shown in FIG. 8 or 9, an interconnection layer 8 is formed on a side of the connection terminals 3 facing away from the semiconductor device, and external terminals 9 is formed on a side of the interconnection layer 8 facing away from the connection terminals 3. The interconnect layer 8 is electrically connected to the connection terminals 3 and the external terminals 9, and the external terminals 9 are used to connect external devices, so that the electrical connection of the semiconductor device 1 to external devices is achieved.

The interconnect layer 8 may be fabricated using all processes known to those skilled in technology and will not be described in detail herein. The interconnect layer 8 includes a redistribution layer 82 and an insulation layer 81, and the connection terminals 3 is electrically connected to the external terminals 9 through the redistribution layer 82.

It should be noted that FIGS. 8 to 9 only exemplarily illustrate that the external terminals 9 are solder balls, but do not constitute a limitation of the semiconductor packaging method provided by the embodiment of the present disclosure. In other embodiments, the external terminals 9 may be provided as pads or solder columns, which are not limited herein.

On the basis of the foregoing embodiments, the embodiments of the present disclosure further provide a semiconductor assembly, where the semiconductor assembly is packaged by any one of the foregoing semiconductor packaging methods, and has corresponding beneficial effects, and to avoid repetitive description, no further description is given here.

In some embodiments, as shown in step (C) of FIG. 2 or 3, the semiconductor assembly includes: at least one semiconductor device 1, the active surface of the semiconductor device 1 is provided with connecting terminals 3 and a first molding layer 4, the first molding layer 4 covers the connecting terminals and covers the active surface which is not occupied by the connecting terminals 3, and the passive surface of the semiconductor device 1 is provided with first alignment bonding parts 2; a carrier 5 having second alignment bonding parts 6 provided on one side surface thereof, any one of the first alignment bonding parts 2 and the second alignment bonding parts 6 including alignment solder bumps, and the others including alignment pads corresponding to the alignment solder bumps, the semiconductor device 1 being precisely aligned with and fixed to the carrier 5 by the alignment solder bumps being precisely aligned with the alignment bonding pads; the second molding layer 7 is positioned on one side of the carrier 5 facing the semiconductor device 1, covers the surface of the carrier 5 not occupied by the semiconductor device 1 and covers the semiconductor device 1, and fills the gap between the semiconductor device 1 and the carrier 5.

In some embodiments, as shown in FIG. 8 or 9, the semiconductor assembly further comprises: an interconnect layer 8 and external terminals 9, the interconnect layer 8 being located on a side of the connection terminals 3 facing away from the semiconductor device 1, the external terminals 9 being located on a side of the interconnect layer 8 facing away from the connection terminals 3; the interconnect layer 8 includes a redistribution layer 82 and an insulation layer 81, the redistribution layer 82 being electrically connected to the connection terminals 3 and the external terminals 9, the external terminals 9 being for connection to an external device. So arranged, an electrical connection of the semiconductor device 3 with external devices is achieved.

In some embodiments, as shown in FIG. 8, the carrier 5 in the semiconductor assembly is removed by at least one of lift-off, etching, ablation, and grinding processes.

In some embodiments, as shown in FIG. 9, the surface of the second molding layer 7 near the second alignment bonding pads is thinned, and at least a portion of the structure other than the passive side of the semiconductor device 1 is removed to further reduce the thickness of the semiconductor assembly.

In this embodiment, the bonding structure formed after the bonding of the first alignment bonding parts and the second alignment bonding parts includes the first alignment pads 21, the first alignment soldering bumps 22 (or the second alignment soldering bumps 62), and the second alignment bonding pads 61. All structures other than the passive surface of the semiconductor device 1, i.e. the first alignment bonding pads 21, the first alignment solder bumps 22 (or the second alignment solder bumps 62) and the second alignment bonding pads 61 and the corresponding second molding layer 7, may be removed, and also some structures other than the passive surface of the semiconductor device 1, such as only the second alignment bonding pads 61 and the corresponding second molding layer 7, or structures where the first alignment solder bumps 22 (or the second alignment solder bumps 62), the second alignment bonding pads 61 and the corresponding second molding layer 7 are removed, or structures where the second molding layer 7 is removed to any position other than the passive surface, may be removed.

On the basis of the foregoing implementation manner, the embodiment of the present disclosure further provides an electronic device, where the electronic device includes: the semiconductor device has the corresponding beneficial effects, and to avoid repeated description, the description is omitted.

It should be noted that in this document, relational terms such as “first” and “second” and the like are used solely to distinguish one entity or action from another entity or action without necessarily requiring or implying any actual relationship or order between such entities or actions. Moreover, the terms “comprises,” “comprising,” or any other variation thereof, are intended to cover a non-exclusive inclusion, such that a process, method, material or equipment that comprises a list of elements does not include only those elements but may include other elements not expressly listed or inherent to such process, method, material, or equipment. Without further limitation, an element defined by the phrase “comprising one . . . ” does not exclude the presence of other like elements in a process, method, article, or apparatus that comprises the element.

The foregoing is merely a specific embodiment of the disclosure to enable one skilled in the art to understand or practice the disclosure. Various modifications to these embodiments will be readily apparent to those skilled in technology, and the generic principles defined herein may be applied to other embodiments without departing from the spirit or scope of the disclosure. Thus, the present disclosure is not intended to be limited to the embodiments shown and described herein but is to be accorded the widest scope consistent with the principles and novel features disclosed herein.

1. A semiconductor packaging method, comprising:
providing a semiconductor device and a carrier, the semiconductor device having an active surface and a passive surface opposite to the active surface, wherein the active surface comprises connecting terminals and a first molding layer covering the active surface and the connecting terminals, the passive surface comprises first alignment bonding parts, the surface of one side of the carrier is provided with second alignment bonding parts corresponding, respectively, to the first alignment bonding parts, one of each of the first alignment bonding parts and a corresponding one of the second alignment bonding parts includes an alignment solder bump, and the other one of the each of the first alignment bonding parts and the corresponding one of the second alignment bonding parts includes an alignment pad;
aligning the alignment solder bumps substantially with the alignment bonding pads, and performing fusion bonding on the alignment solder bumps and the alignment bonding pads to further align the semiconductor device more accurately with the carrier and to fix the semiconductor device to the carrier; and
forming a second molding layer, wherein the second molding layer covers portions of the surface of the side surface of the carrier not occupied by the semiconductor device and covers the semiconductor device, and the second molding layer fills a gap between the semiconductor device and the carrier.

2. The semiconductor packaging method of claim 1, wherein performing the fusion bonding of alignment solder bumps and corresponding alignment pads comprises:
heating the alignment solder bumps so that the alignment solder bumps are in an at least partially molten state; and
bonding the alignment solder bumps in an at least partially molten state with the alignment bonding pads.

3. The semiconductor packaging method of claim 1, wherein the first alignment bonding parts comprises first alignment pads, and before providing the semiconductor device, the semiconductor packaging method further comprises:
forming a first metal layer on the passive surface;
forming a patterned first photoresist layer on one side of the first metal layer away from the semiconductor device, the first photoresist layer having first openings exposing the first metal layer;
etching the first metal layer exposed by the first openings based on the patterned first photoresist layer to form first alignment pads under the photoresist layer; and
removing the first photoresist layer to expose the first alignment pads.

4. The semiconductor packaging method of claim 3, wherein the first alignment bonding parts comprises first alignment solder bumps; the semiconductor packaging method further comprises the steps of:
forming first alignment solder bumps on one side of the first alignment pads away from the semiconductor device.

5. The semiconductor packaging method of claim 1, wherein the second alignment bonding parts comprises second alignment pads; before the providing of the carrier, the semiconductor packaging method further comprises:
forming a second metal layer on one side of the carrier;
forming a patterned second photoresist layer on one side of the second metal layer away from the carrier, the second photoresist layer comprises second openings, and the second openings exposing the second metal layer;
etching the metal layer exposed by the second openings based on the second photoresist layer to form second alignment pads under the photoresist layer;
and removing the second photoresist layer to expose the second alignment pads.

6. The semiconductor packaging method of claim 5, wherein the second alignment bonding parts comprises second alignment solder bumps; the semiconductor packaging method further comprises the steps of:
forming second alignment solder bumps on one side of the second alignment pads away from the carrier.

7. The semiconductor packaging method of claim 1, wherein the semiconductor packaging method further comprises:
forming connection terminals on the active surface prior to the first alignment bonding parts being formed on the passive surface; and
forming the first molding layer on one side of the connecting terminals away from the semiconductor device, wherein the first molding layer covers the active surface and the connecting terminals.

8. The semiconductor packaging method of claim 1, further comprising:
removing the carrier using at least one of lift-off, etching, ablation, and grinding processes.

9. The semiconductor packaging method of claim 8, wherein after removing the carrier, the semiconductor packaging method further comprises:
thinning the surface of the second molding layer near one side of the second alignment bonding.

10. The semiconductor packaging method of claim 1, further comprising:
thinning the first molding layer to expose the connecting terminals; and
forming an interconnection layer and external terminals on the surface of one side of the first molding layer exposing the connection terminals, wherein the connection terminals are electrically connected with the external terminals through the interconnection layer.

11. A semiconductor assembly made using the semiconductor packaging method according to claim 1.

12. An electronic device, comprising the semiconductor assembly of claim 11.
